(19) United States
(12) Patent Application Publication
(10) Pub. No.: US 2015/0269911 A1
(43) Pub. Date: Sep. 24, 2015

(54) CHIP ON FILM PACKAGES INCLUDING PLURALITY OF OUTPUT PADS CONNECTED TO FILM WIRES

(71) Applicant: Samsung Electronics Co., Ltd., Suwon-si (KR)

(72) Inventors: Sungpil CHOI, Yongin-si (KR); Hyungwoo Yu, Hwaseong-si (KR); Narae Shin, Yongin-si (KR); Kijoon Kim, Suwon-si (KR); Yong-Hun Kim, Seoul (KR); SooJin Park, Suwon-si (KR); Myoungsik Suh, Hwaseong-si (KR); Jae-Bum Lee, Gwangmyeong-si (KR); EunJong Jang, Osan-si (KR)

(21) Appl. No.: 14/581,356

(22) Filed: Dec. 23, 2014

(30) Foreign Application Priority Data
Mar. 18, 2014 (KR) 10-2014-0031695

(51) Int. Cl. G09G 5/18; H01L 23/50; H01L 23/522; H01L 23/00; H01L 27/12; H01L 23/528

(52) U.S. Cl. CPC G09G 5/18; H01L 27/124; H01L 23/528; H01L 23/5226; H01L 24/06; H01L 23/50; H01L 2224/06179; H01L 2924/1426; G09G 2300/0404

(57) ABSTRACT

Provided is a chip on film package including an integrated circuit chip and a film. The integrated circuit chip includes one or more first output pads along a first longer side, and one or more second output pads along a second longer side which faces the first longer side. The film includes a lower film, a plurality of film conducting wires on one face of the lower film, and an upper film on the plurality of film conducting wires. Each of the plurality of film conducting wires may be spaced apart from an adjacent film conducting wire. The first output pads and the second output pads are respectively connected to the plurality of film conducting wires electrically. The plurality of film conducting wires is a single layer between the upper film and the lower film.

### CROSS-REFERENCE TO RELATED APPLICATION

This U.S. non-provisional patent application claims priority under 35 U.S.C. §119 to Korean Patent Application No. 10-2014-0031695, filed on Mar. 18, 2014, in the Korean Intellectual Property Office, the entire disclosure of which is hereby incorporated herein by reference.

### FIELD

Some embodiments of the inventive concept relate generally to semiconductor packages, and more particularly, to a chip on film package including a film and an integrated circuit chip mounted on the film.

### BACKGROUND

Semiconductor products, such as a semiconductor package, may be produced by various packaging technologies. In particular, a semiconductor integrated circuit used in an operation of a display device may be embodied in a form of a chip and may be mounted on a thin film. The semiconductor package having a structure in which an integrated circuit chip is mounted on a film may be called a “chip on film” package. The integrated circuit chip included in the chip on film package may perform a function of a gate driver for applying a driving signal to pixels of a display panel or a source driver for transmitting data to be displayed on the pixels of the display panel.

Display panels may be mass produced, including a quad ultra high definition (QUHD) display panel having resolution of 7680×4320, a full high definition (FHD) display panel having resolution of 1920×1080, and an ultra high definition (UHD) display panel having resolution of 3840×2160.

To drive and operate a display panel that includes many pixels, a number of integrated circuit chips may be connected to the display panel. However, since a size of the display panel is limited, there may be a limit on the number of the integrated circuit chips that can be connected to the display panel. Thus, one integrated circuit chip may be connected to more output conducting wires.

### SUMMARY

Some embodiments of the inventive concept provide a chip on film package. The chip on film package may include an integrated circuit chip and a film. The integrated circuit chip may include one or more first output pads along a first edge of a surface of the integrated circuit chip, and one or more second output pads along a second edge of the surface of the integrated circuit chip which faces the first edge. A length of the first edge and a length of the second edge may each be greater than lengths of third and fourth edges of the surface. The film may include a lower film, a plurality of film conducting wires on a face of the lower film, and an upper film on the plurality of film conducting. Each of the plurality of film conducting wires may be spaced apart from an adjacent film conducting wire. The one or more first output pads and the one or more second output pads may be electrically connected to respective ones of the plurality of film conducting wires. The film conducting wires may be a single layer between the upper film and the lower film. Each of the film conducting wires may extend under the first edge of the surface of the integrated circuit chip.

In some embodiments, the one or more first output pads and the one or more second output pads may be electrically connected to respective ones of the plurality of film conducting wires through via-holes, respectively.

In some embodiments, each of the via-holes may penetrate the upper film.

In some embodiments, the integrated circuit chip may include one or more input pads along the second edge of the surface of the integrated circuit chip.

In some embodiments, the integrated circuit may include more first output pads than second output pads.

In some embodiments, each of the film conducting wires may have a form of a straight line.

In some embodiments, the one or more first output pads and the one or more second output pads may be alternately disposed when the integrated circuit chip is viewed from the first edge or the second edge.

In some embodiments, the one or more first output pads and the one or more second output pads may be connected to the plurality of film conducting wires in one-to-one correspondence.

In some embodiments, the respective ones of the film conducting wires respectively connected to the one or more first output pads and the respective ones of the film conducting wires respectively connected to the one or more second output pads may be alternately disposed in turn.

In some embodiments, the integrated circuit chip may be at least one of a gate driver integrated circuit chip and a source driver integrated circuit chip.

According to some embodiments of the inventive concept, a chip on film package may include a film and an integrated circuit chip. The film may include a plurality of film conducting wires inside of the film. Each of the plurality of film conducting wires may be spaced apart from any adjacent film conducting wire. The integrated circuit chip may be on a face of the film. The integrated circuit chip may include one or more first output pads along a first edge of a surface of the integrated circuit chip, and one or more second output pads along a second edge of the surface of the integrated circuit chip which faces the first edge. A length of the first edge and a length of the second edge may each be greater than lengths of third and fourth edges of the surface. The one or more first output pads and the one or more second output pads may be electrically connected to respective ones of the plurality of film conducting wires. The film conducting wires may be a single layer inside the film. Each of the plurality of film conducting wires may extend under the first edge of the surface of the integrated circuit chip.

In some embodiments, the one or more first output pads and the one or more second output pads may be electrically connected to the respective ones of the plurality of film conducting wires through via-holes, respectively.

In some embodiments, each of the via-holes may penetrate the face of the film.

In some embodiments, the integrated circuit chip may further include one or more input pads along the second edge of the surface of the integrated chip, and the integrated circuit chip may include more first output pads than second output pads.

In some embodiments, each of the plurality of film conducting wires may have a form of a straight line.

In some embodiments, the integrated circuit chip may be at least one of a gate driver integrated circuit chip and a source driver integrated circuit chip.

Some embodiments of the inventive concept provide a display system. The display system may include a chip on film package and a display device. The chip on film package may include an integrated circuit chip and a film. The integrated circuit chip may include one or more first output pads along a first edge of a surface of the integrated circuit chip, and one or more second output pads along a second edge of the surface of the integrated circuit chip which faces the first edge. A length of the first edge and a length of the second edge may each be greater than lengths of third and fourth edges of the surface. The film may include a lower film, a plurality of film conducting wires on a face of the lower film, and an upper film on the plurality of film conducting wires. Each of the film conducting wires may be spaced apart from an adjacent film conducting wire. The display device may include a display panel, a frame rate converter and a timing controller. The frame rate controller may be configured to process data that controls a frequency of frames displayed on the display panel. The timing controller may be configured to control an image displayed on the display panel. The one or more first output pads and the one or more second output pads may be electrically connected to respective ones of the plurality of film conducting wires through via-holes, in one-to-one correspondence. The film conducting wires may be a single layer between the upper film and the lower film.

In some embodiments, each of the plurality of film conducting wires may extend under the first edge of the surface of the integrated chip.

In some embodiments, of the respecting ones of the film conducting wires respectively connected to the one or more first output pads and of the respective ones of the film conducting wires respectively connected to the one or more second output pads may be alternately disposed.

In some embodiments, the integrated circuit chip may be at least one of a gate driver integrated circuit chip and a source driver integrated circuit chip.

### BRIEF DESCRIPTION OF THE DRAWINGS

The accompanying figures are included to provide a further understanding of the present inventive concept, and are incorporated in and constitute a part of this specification. The drawings illustrate some embodiments of the present inventive concept and, together with the description, serve to explain principles of the present inventive concept.

FIG. 1 is a schematic block diagram illustrating a chip on film package according to some embodiments of the inventive concept.

FIGS. 2 to 9 are cross sectional views illustrating configurations according to some embodiments of the chip on film package of FIG. 1.

FIG. 10 is a block diagram illustrating a display device including a gate driver and a source driver that are to be mounted on a chip on film package in accordance with some embodiments of the inventive concept.

### DETAILED DESCRIPTION OF THE EMBODIMENTS

Embodiments are described in detail with reference to the accompanying drawings. The inventive concept may, however, be embodied in various different forms, and should not be construed as being limited only to the illustrated embodiments set forth herein. Rather, these embodiments are provided as examples so that this disclosure will be thorough and complete, and will fully convey the concept of the inventive concept to those skilled in the art. In the drawings, the size and relative sizes of layers and regions may be exaggerated for clarity. Unless otherwise noted, like reference numerals denote like elements throughout the attached drawings and written description, and thus descriptions may not be repeated.

Unless otherwise defined, all terms (including technical and scientific terms) used herein have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and/or the inventive concept, and will not be interpreted in an idealized or overly formal sense unless expressly so defined herein.

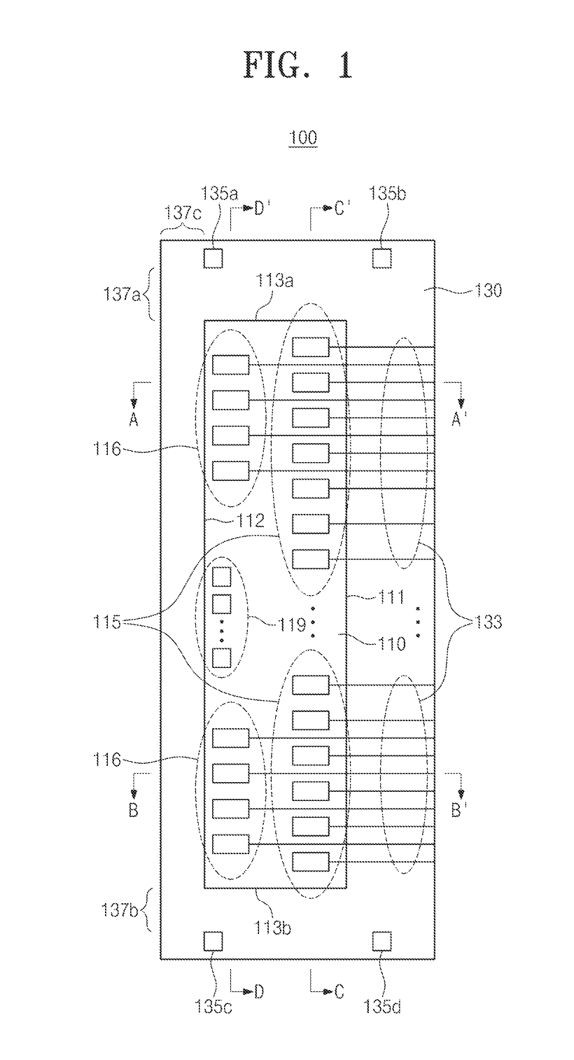

FIG. 1 is a schematic diagram illustrating a chip on film package in accordance with some embodiments of the inventive concept. Referring to FIG. 1, a chip on film package 100 may include an integrated circuit chip 110 and a film 130. In some embodiments, when the chip on film package 100 is connected to a display panel, the integrated circuit chip 110 may be an integrated circuit chip being used as a gate driver and/or a source driver. Hereinafter, the chip on film package 100 will be referred to for illustrative purposes as being connected to the display panel. However, the chip on film package 100 may not connect to a display panel and may connect to other devices.

The integrated circuit chip 110 may be formed of a first longer side 111, a second longer side 112, and two shorter sides 113a and 113b. The first longer side 111 and the second longer side 112 may face each other, and the two shorter sides 113a and 113b may face each other.

The integrated circuit chip 110 may include one or more basic output pads 115. The basic output pads 115 may be disposed along the first longer side 111. Moreover, the integrated circuit chip 110 may further include one or more extended output pads 116 which may increase the number of output pads arranged per unit area. The extended output pads 116 may be disposed along the second longer side 112. Herein, the first and second longer sides 111 and 112 are names set for convenience of description. A part called the first longer side 111 and a part called the second longer side 112 may be exchanged.

According to some embodiments of the inventive concept, an integrated circuit chip 110 with many output pads may be provided when the integrated circuit chip 110 includes one or more extended output pads 116. Also, the number of output pads disposed per unit area may be increased by a disposition of one or more output pads 116 and thereby a size of the integrated circuit chip 110 may be reduced. That is, an efficiency of a disposition of the output pad may be improved.

The integrated circuit chip 110 may further include one or more input pads 119. The input pads 119 may be disposed along the second longer side 112. That is, the extended output pads 116 and the input pads 119 may be disposed in a row along the second longer side 112. One or more of the input pads 119 may be connected to an input conducting wire for receiving an input signal. One or more of the input pads 119 may perform a specific function according to the received input signal.

In some embodiments, the input pads 119 may be disposed in an area corresponding to the center of the second longer side 112, and the extended output pads 116 may be disposed in an area corresponding to the edge of the second longer side 112. This is only illustrative, and a disposition of the extended output pads 116 and the input pads 119 may be changed in various forms. Further, the number of basic output pads 115, the number of extended output pads 116 and the number of input pads 119 may be changed to be different from such as illustrated in FIG. 1. As illustrated in FIG. 1, when the input pads 119 are further disposed along the second longer side 112, the number of basic output pads 115 may be greater than the number of extended output pads 116.

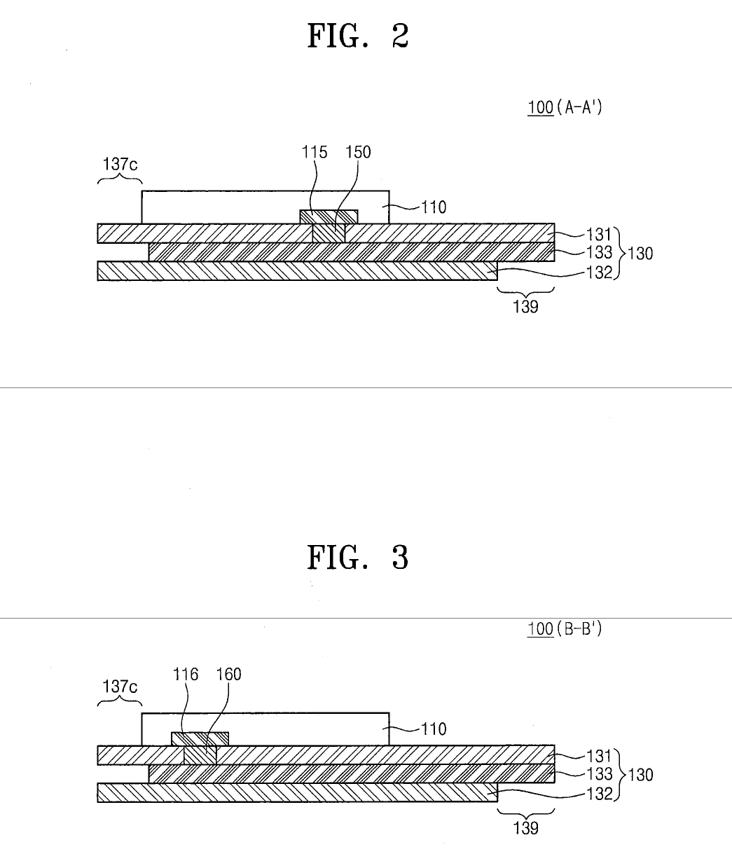

In some embodiments, the film 130 may include a plurality of film conducting wires 133. In some embodiments, the film 130 may include a lower cover. The plurality of film conducting wires 133 may be disposed on a face of the lower cover with interval between the plurality of film conducting wires 133. That is, each of the plurality of film conducting wires 133 may be spaced apart from an adjacent film conducting wire. Further, the film 130 may include an upper cover. The upper cover may cover the plurality of film conducting wires 133 on the face of the lower cover. In some embodiments, the film 130 may have a plurality of film conducting wires 133 inside of the film 130. In such embodiments, each of the plurality of film conducting wires 133 may be spaced apart from an adjacent film conducting wire. Detailed descriptions with respect to the film 130 are provided with reference to FIGS. 2 to 9.

The basic output pads 115 may be electrically connected to respective ones of the plurality of film conducting wires 133. The extended output pads 116 may also be electrically connected to respective ones of the plurality of film conducting wires 133. The basic output pads 115 and the extended output pads 116 may provide output signals to another device or circuit (for example, a display panel) through the respective ones of the plurality of film conducting wires 133 that are electrically connected to the basic output pads 115 and the extended output pads 116. As illustrated in FIG. 1, ones of the plurality of film conducting wires 133 may have a form of a straight line. Ones of the plurality of film conducting wires 133 may be disposed to cross below the first longer side 111.

In some embodiments, one or more extended output pads 116 may be disposed together with the input pads 119 which may further increase the number of output pads disposed per unit area. In some embodiments, ones of the output pads 116 are not connected to the plurality of film conducting wires 133 but are connected to output conducting wires. The additional output conducting wires may be provided on available space (refer to 137a, 137b and/or 137c). In such embodiments, the additional output conducting wires may be implemented in a configuration surrounding the integrated circuit chip 110 above the available space 137a, 137b and/or 137c while each of the additional output conducting wires may have a bent shape such as a character “⊂” or “Π”.

However, if the additional output conducting wires are provided on the available space 137a, 137b and/or 137c, the output conducting wires that are connected to the extended output pads 116 may have a bent shape while the output conducting wires that are connected to the basic output pads 115 may have a form of a straight line. Thus, a difference of fan-out may occur between the output conducting wires that are connected to the basic output pads 115 and the output conducting wires that are connected to the extended output pads 116. FIG. 1 schematically illustrates the chip on film package in order to help understanding of the inventive concept. However, if the actual number of output pads increases to be greater than the number of output pads illustrated in FIG. 1, the difference of fan-out between the output conducting wires may also increase. If the difference of fan-out between the output conducting wires increases, a resistance characteristic of ones of the output conducting wires may become different from one another. If the resistance characteristic of ones of the output conducting wires becomes different, an image quality characteristic of a display panel connected to the chip on film package 100 may become degraded.

Moreover, there may be a limitation in a size which the chip on film package 100 and the integrated circuit chip 110 may have. Thus, there may be a limitation in the number of output conducting wires that may be provided on the available space 137a, 137b and/or 137c. Consequently, the number of the extended output pads 116 that are connected to the additional output conducting wires may also be limited.

However, in some embodiments of the inventive concept, the additional output conducting wires that are connected to the extended output pads 116 may not be provided. Instead, in some embodiments of the inventive concept such additional output conducting wires may be embodied based on a film level routing (FLR). That is, in some embodiments of the inventive concept, the basic output pads 115 and the extended output pads 116 may be respectively connected to the plurality of film conducting wires 133 that may be disposed inside the film 130.

According to some embodiments of the inventive concept, a difference of fan-out between the output conducting wires that are connected to the basic output pads 115 and the output conducting wires that are connected to the extended output pads 116 may be reduced. The difference of fan-out between ones of the film conducting wires 133 that are connected to respective ones of the basic output pads 115 and ones of the film conducting wires 133 that are connected to ones of the extended output pads 116 may be less than a length of the shorter sides 113a and 113b of the integrated circuit chip 110. Thus, if the chip on film package 100 is connected to a display panel, the display panel having a high image quality characteristic may be provided. Furthermore, since there may be no limitation in the number of the extended output pads 116, more output pads may be disposed per unit area.

The film 130 may include one or more fixing marks 135a, 135b, 135c and 135d. The fixing marks 135a, 135b, 135c and 135d may fix the chip on film package 100 in a space on which the chip on film package 100 is disposed.

FIG. 2 is a cross sectional view illustrating a configuration that may be shown in a cross section obtained when cutting the chip on film package 100 along the line A-A′ of FIG. 1.

Referring to FIG. 2, as described with reference to FIG. 1, a film 130 may include an upper cover 131 and a lower cover 132. The film 130 may further include a plurality of film conducting wires 133 that may be disposed on a face of the lower cover 132 and may be covered with the upper cover 131. The upper cover 131 and the lower cover 132 are names set for convenience of description. A part called the upper cover 131 and a part called the lower cover 132 may be exchanged.

In some embodiments, the chip on film package 100 may have a physical form or configuration different from that illustrated in FIG. 2. For instance, when the upper cover 131 and the lower cover 132 are formed by a flexible material, the upper cover 131 and the lower cover 132 may completely cover the plurality of film conducting wires 133 in an area corresponding to the available space 137c. FIG. 2 is only a schematic diagram representing some embodiments of the inventive concept.

In some embodiments, ones of the plurality of film conducting wires 133 may have a form of a straight line. In some embodiments, ones of the plurality of film conducting wires 133 may be disposed to cross below a first longer side 111 (refer to FIG. 1). In particular, as illustrated in FIG. 2, the plurality of film conducting wires 133 may be disposed between the upper cover 131 and the lower cover 132 as a single layer.

The integrated circuit chip 110 may be disposed on a face of the upper cover 131. The integrated circuit chip 110 may include one or more basic output pads 115 that may be disposed along the first longer side 111. In some embodiments, ones of the basic output pads 115 may be electrically connected to respective ones of the plurality of film conducting wires 133 through respective via-holes 150. The via-holes 150 may penetrate the upper cover 131.

In some embodiments, a connection area 139 may be provided in the chip on film package 100. The connection area 139 may be an area for connecting the plurality of film conducting wires 133 with, for instance, a display panel. In such embodiments, the lower cover 132 may extend only to the front of the connection area 139. In the connection area 139, ones of the plurality of film conducting wires 133 may be exposed to the outside in order to be connected to the display panel. This is only illustrative and the connection area 139 may be embodied in a different form. For instance, the connection area 139 may be embodied to include via-holes penetrating the lower cover 132, and ones of the plurality of film conducting wires 133 may be connected to the display panel through respective via-holes.

FIG. 3 is a cross sectional view illustrating a configuration that may be shown in a cross section obtained when cutting the chip on film package 100 along the line B-B′ of FIG. 1.

Referring to FIG. 3, as described above, the film 130 may include the upper cover 131 and the lower cover 132. The film 130 may further include the plurality of film conducting wires 133 that may be disposed on a face of the lower cover 132 and may be covered with the upper cover 131. In some embodiments, ones of the plurality of film conducting wires 133 may have a form of a straight line. In some embodiments, ones of the plurality of film conducting wires 133 may be disposed to cross below a first longer side 111 (refer to FIG. 1). In particular, as illustrated in FIG. 3, the plurality of film conducting wires 133 may be disposed between the upper cover 131 and the lower cover 132 as a single layer.

The integrated circuit chip 110 may be disposed on a face of the upper cover 131. The integrated circuit chip 110 may include one or more extended output pads 116 that may be disposed along the second longer side 112 (refer to FIG. 1). Ones of the extended output pads 116 may be electrically connected to respective ones of the plurality of film conducting wires 133 through respective via-holes 160. The via-holes 160 may penetrate the upper cover 131.

A connection area 139 may be provided in the chip on film package 100. The connection area 139 may be an area for connecting the plurality of film conducting wires 133 with, for instance, a display panel. Detailed descriptions with respect to the connection area 139 are mentioned with reference to FIG. 2.

According to the configurations illustrated in FIGS. 2 and 3, the additional output conducting wires connected to the extended output pads 116 may not be provided on the available space 137c. Instead, in the embodiments of the inventive concept illustrated in FIG. 3, ones of the extended output pads 116 may be electrically connected to ones of the plurality of film conducting wires 133 having a form of a straight line. As described above, according to some embodiments of the inventive concept, more output pads may be disposed per unit area. Further, a display device having a high image quality characteristic may be provided.

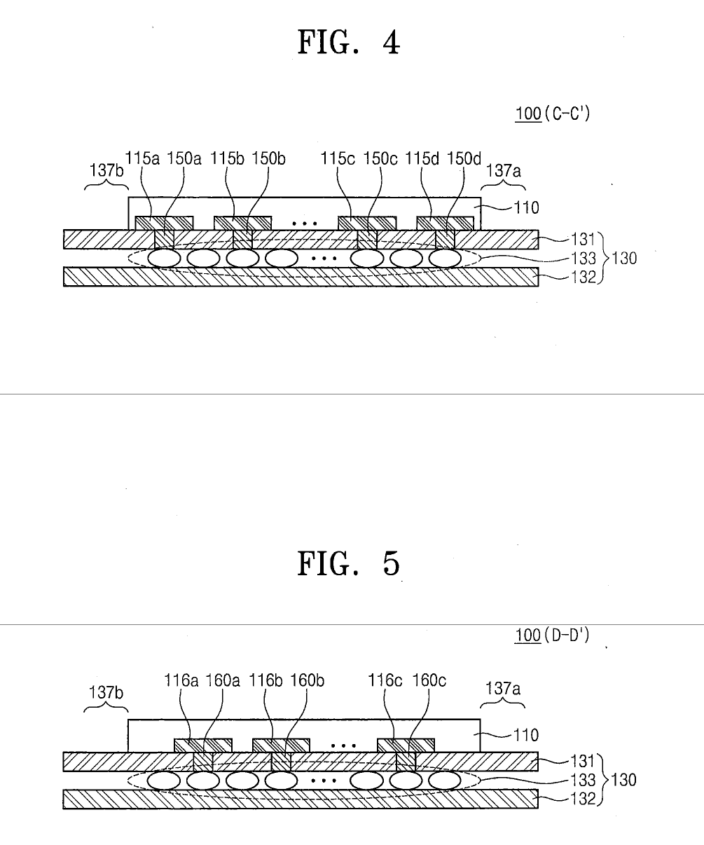

FIG. 4 is a cross-sectional view illustrating a configuration that may be shown in a cross section obtained when cutting the chip on film package 100 along the line C-C′ of FIG. 1.

Referring to FIG. 4, as described above, the film 130 may include the upper cover 131 and the lower cover 132. The film 130 may further include the plurality of film conducting wires 133 that may be disposed on a face of the lower cover 132 and may be covered with the upper cover 131. In particular, the plurality of film conducting wires 133 may be disposed between the upper cover 131 and the lower cover 132 as a single layer.

In some embodiments, the chip on film package 100 may have a physical form or configuration different from that illustrated in FIG. 4. For instance, when the upper cover 131 and the lower cover 132 are formed by a flexible material, the upper cover 131 and the lower cover 132 may completely cover the plurality of film conducting wires 133 in an area corresponding to the available space 137a and 137b. Each space between the plurality of film conducting wires 133 may be surrounded by the upper cover 131 and the lower cover 132 or may be filled with an insulating material. FIG. 4 is only a schematic diagram representing some embodiments of the inventive concept.

The integrated circuit chip 110 may be disposed on a face of the upper cover 131. The integrated circuit chip 110 may include basic output pads 115a, 115b, 115c and 115d that may be disposed along the first longer side 111 (refer to FIG. 1). In some embodiments, the basic output pads 115a, 115b, 115c and 115d may be electrically connected to respective ones of the plurality of film conducting wires 133 through respective via-holes 150a, 150b, 150c and 150d. The via-holes 150a, 150b, 150c and 150d may penetrate the upper cover 131.

FIG. 5 is a cross sectional view illustrating a configuration that may be shown in a cross section obtained when cutting the chip on film package 100 along the line D-D′ of FIG. 1.

Referring to FIG. 5, as described above, the film 130 may include the upper cover 131 and the lower cover 132. The film 130 may further include the plurality of film conducting wires 133 that may be disposed on a face of the lower cover 132 and may be covered with the upper cover 131. In particular, the plurality of film conducting wires 133 may be disposed between the upper cover 131 and the lower cover 132 as a single layer.

The integrated circuit chip 110 may be disposed on a face of the upper cover 131. The integrated circuit chip 110 may include one or more extended output pads 116a, 116b and 116c that may be disposed along the second longer side 112 (refer to FIG. 1). In some embodiments, the extended output pads 116a, 116b and 116c may be electrically connected to respective ones of the plurality of film conducting wires 133 through respective via-holes 160a, 160ba and 160c. The via-holes 160a, 160ba and 160c may penetrate the upper cover 131.

Referring to FIGS. 4 and 5, when viewing the integrated circuit chip 110 from the first longer side 111 (or from the second longer side 112), each of the basic output pads 115a, 115b, 115c and 115d and each of the extended output pads 116a, 116b and 116c may be disposed in turn. That is, when viewing the integrated circuit chip 110 from the first longer side 111 (or from the second longer side 112), one extended output pad (e.g., 116a) may be disposed between the two basic output pads (e.g., 115a and 115b), and one basic output pad (e.g., 115b) may be disposed between the two extended output pads (e.g., 116a and 116b).

In some embodiments, the basic output pads 115a, 115b, 115c and 115d and the extended output pads 116a, 116b and 116c may be electrically connected to respective ones of the plurality of film conducting wires 133 in one-to-one correspondence. That is, each of the basic output pads 115a, 115b, 115c and 115d and each of the extended output pads 116a, 116b and 116c may be connected to a respective one of the plurality of film conducting wires 133. In such embodiments, each of the plurality of film conducting wires 133 that is respectively connected to the basic output pads 115a, 115b, 115c and 115d and each of the plurality of film conducting wires 133 that is respectively connected to the extended output pads 116a, 116b and 116c may be disposed in turn. That is, one film conducting wire 133 connected to one extended output pad (e.g., 116a) may be disposed between two film conducting wires 133 respectively connected to two basic output pads (e.g., 115a and 115b), and one film conducting wire 133 connected to one basic output pad (e.g., 115b) may be disposed between two film conducting wires 133 respectively connected to two extended output pads (e.g., 116a and 116b).

According to the embodiments illustrated in FIGS. 4 and 5, the additional output conducting wires connected to the extended output pads 116a, 116b and 116c may not be provided on the available space 137a and 137b. Instead, in the embodiments illustrated in FIG. 5, the extended output pads 116a, 116b and 116c may be electrically connected to respective ones of the plurality of film conducting wires 133. As described above, according to some embodiments of the inventive concept, more output pads may be disposed per unit area. Further, a display device having a high image quality characteristic may be provided.

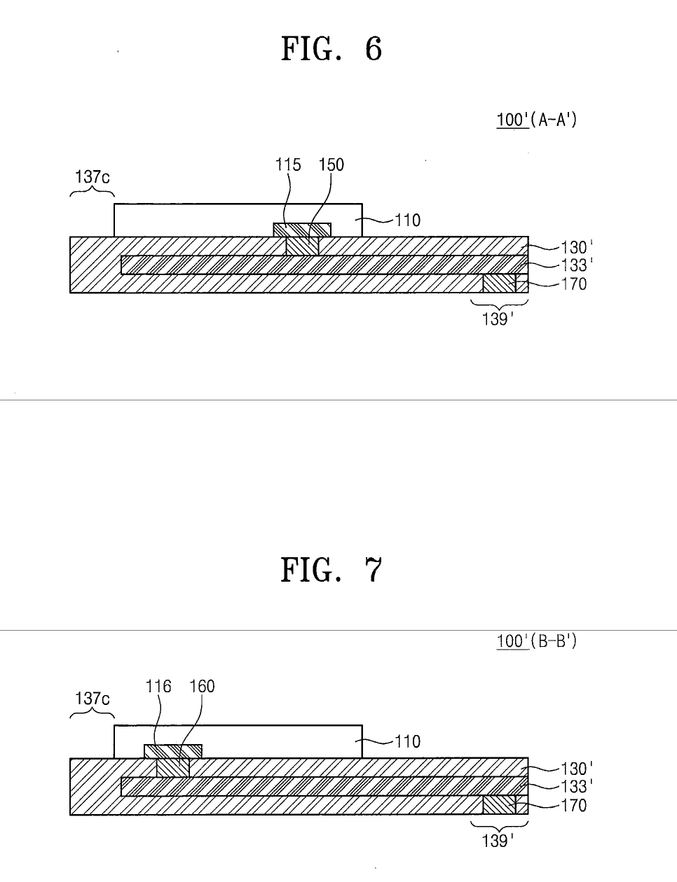

FIG. 6 is a cross sectional view illustrating a configuration that may be shown in a cross section obtained when cutting the chip on film package 100 along the line A-A′ of FIG. 1. However, a film 130′ included in a chip on film package 100′ of FIG. 6 may have a different form from the film 130 included in the chip on film package 100 of FIG. 2.

Referring to FIG. 6, the film 130′ may have a plurality of film conducting wires 133′ inside of the film 130′. Further, each of the plurality of film conducting wires 133′ may be spaced apart from an adjacent film conducting wire. When the film 130′ is thick, the plurality of film conducting wires 133′ may be inside of the film 130′. In some embodiments, ones of the plurality of film conducting wires 133′ may have a form of a straight line. In particular, as illustrated in FIG. 6, the plurality of film conducting wires 133′ may be disposed inside the film 130′ as a single layer.

In some embodiments, the integrated circuit chip 110 may be disposed on a first face of the film 130′. In such embodiments, ones of the plurality of film conducting wires 133′ may be disposed below a face of the integrated circuit chip 110. In particular, ones of the plurality of film conducting wires 133′ may be disposed to cross below the first longer side 111 (refer to FIG. 1).

The integrated circuit chip 110 may include basic output pads 115 that may be disposed along the first longer side 111. In some embodiments, ones of the basic output pads 115 may be electrically connected to respective ones of the plurality of film conducting wires 133′ through respective via-holes 150. The via-holes 150 may penetrate the first face of the film 130′.

A connection area 139′ may be provided in the chip on film package 100. The connection area 139′ may be an area for connecting the plurality of film conducting wires 133′ with, for instance, a display panel. The connection area 139′ may include via-holes 170 penetrating a second face of the film 130′. In the connection area 139′, ones of the plurality of film conducting wires 133′ may be connected to the display panel through respective via-holes 170. This is only illustrative and the connection area 139′ may be embodied in a different form. For instance, the second face of the film 130′ may extend only to the front of the connection area 139′, and ones of the plurality of film conducting wires 133′ may be exposed to the outside to be connected to the display panel.

FIG. 7 is a cross sectional view illustrating a configuration that may be shown in a cross section obtained when cutting the chip on film package 100 along the line B-B′ of FIG. 1. However, a film 130′ included in a chip on film package 100′ of FIG. 7 may have a different form from the film 130 included in the chip on film package 100 of FIG. 3.

Referring to FIG. 7, the film 130′ may have a plurality of film conducting wires 133′ inside of the film 130′. Further, each of the plurality of film conducting wires 133′ may be spaced apart from an adjacent film conducting wire. When the film 130′ is thick, the plurality of film conducting wires 133′ may be inside of the film 130′. In some embodiments, each of the plurality of film conducting wires 133′ may have a form of a straight line. In particular, the plurality of film conducting wires 133′ may be disposed inside the film 130′ as a single layer.

In some embodiments, the integrated circuit chip 110 may be disposed on a first face of the film 130′. In such embodiments, ones of the plurality of film conducting wires 133′ may be disposed below a face of the integrated circuit chip 110. In particular, ones of the plurality of film conducting wires 133′ may be disposed to cross below the first longer side 111 (refer to FIG. 1).

The integrated circuit chip 110 may include the extended output pads 116, which may be disposed along the second longer side 112 (refer to FIG. 1). In some embodiments, ones of the extended output pads 116 may be electrically connected to respective ones of the plurality of film conducting wires 133′ through respective via-holes 160. The via-holes 160 may penetrate a first side of the film 130′.

A connection area 139′ may be provided in the chip on film package 100. The connection area 139′ may be an area for connecting the plurality of film conducting wires 133′ with, for instance, a display panel. Detailed descriptions with respect to the connection area 139′ are mentioned with reference to FIG. 6.

According to the configurations illustrated in FIGS. 6 and 7, the additional output conducting wires connected to the extended output pads 116 may not be provided on the available space 137c. Instead, in the embodiments of the inventive concept illustrated in FIG. 7, ones of the extended output pads 116 may be electrically connected to one of the plurality of film conducting wires 133′ having a form of a straight line. As described above, according to some embodiments of the inventive concept, more output pads may be disposed per unit area. Further, a display device having a high image quality characteristic may be provided.

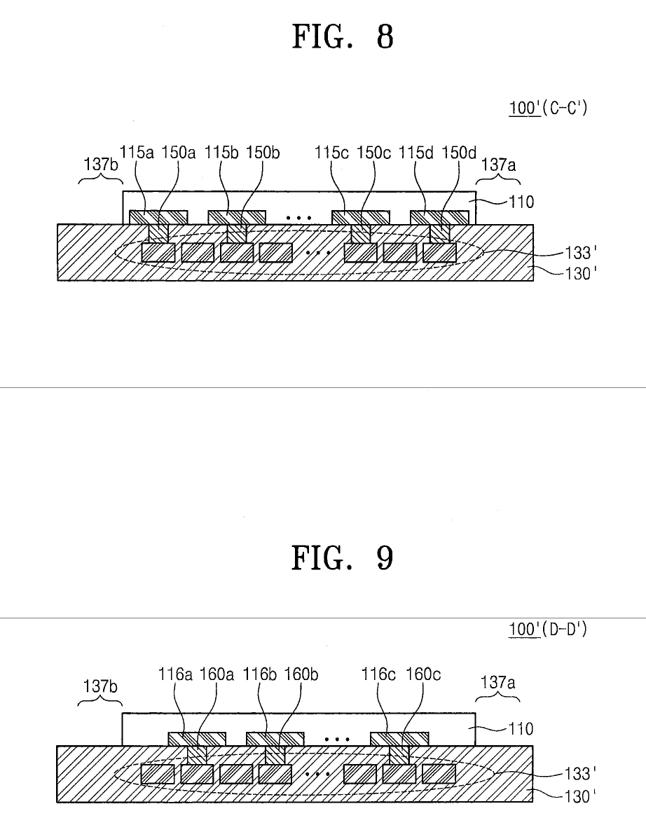

FIG. 8 is a cross sectional view illustrating a configuration that may be shown in a cross section obtained when cutting the chip on film package 100 along the line C-C′ of FIG. 1. However, a film 130′ included in a chip on film package 100′ of FIG. 8 may have a different form from the film 130 included in the chip on film package 100 of FIG. 4.

Referring to FIG. 8, the film 130′ may have a plurality of film conducting wires 133′ inside of the film 130′. Further, each of the plurality of film conducting wires 133′ may be spaced apart from an adjacent film conducting wire. When the film 130′ is thick, the plurality of film conducting wires 133′ may be inside of the film 130′. In particular, the plurality of film conducting wires 133′ may be disposed inside the film 130′ as a single layer.

In some embodiments, the integrated circuit chip 110 may be disposed on a first face of the film 130′. The integrated circuit chip 110 may include basic output pads 115a, 115b, 115c and 115d that may be disposed along the first longer side 111 (refer to FIG. 1). In some embodiments, the basic output pads 115a, 115b, 115c and 115d may be electrically connected to respective ones of the plurality of film conducting wires 133′ through respective via-holes 150a, 150b, 150c and 150d. The via-holes 150a, 150b, 150c and 150d may penetrate the first face of the film 130′.

FIG. 9 is a cross sectional view illustrating a configuration that may be shown in a cross section obtained when cutting the chip on film package 100 along the line D-D′ of FIG. 1. However, a film 130′ included in a chip on film package 100′ of FIG. 9 may have a different form from the film 130 included in the chip on film package 100 of FIG. 5.

Referring to FIG. 9, the film 130′ may have a plurality of film conducting wires 133′ inside of the film 130′. Further, each of the plurality of film conducting wires 133′ may be spaced apart from an adjacent film conducting wire. When the film 130′ is thick, the plurality of film conducting wires 133′ may be inside of the film 130′. In particular, the plurality of film conducting wires 133′ may be disposed inside the film 130′ as a single layer.

In some embodiments, the integrated circuit chip 110 may be disposed on a first face of the film 130′. The integrated circuit chip 110 may include extended output pads 116a, 116b, and 116c that may be disposed along the second longer side 112 (refer to FIG. 1). In some embodiments, the extended output pads 116a, 116b, and 116c may be electrically connected to respective ones of the plurality of film conducting wires 133′ through respective via-holes 160a, 160b, and 160c. The via-holes 160a, 160b, and 160c may penetrate the first face of the film 130′.

Referring to FIGS. 8 and 9, when viewing the integrated circuit chip 110 from the first longer side 111 (or from the second longer side 112), each of the basic output pads 115a, 115b, 115c and 115d and each of the extended output pads 116a, 116b and 116c may be disposed in turn. That is, when viewing the integrated circuit chip 110 from the first longer side 111 (or from the second longer side 112), one extended output pad (e.g., 116a) may be disposed between the two basic output pads (e.g., 115a and 115b), and one basic output pad (e.g., 115b) may be disposed between the two extended output pads (e.g., 116a and 116b).

In some embodiments, the basic output pads 115a, 115b, 115c and 115d and the extended output pads 116a, 116b and 116c may be electrically connected to respective ones of the plurality of film conducting wires 133′ in one-to-one correspondence. That is, each of the basic output pads 115a, 115b, 115c and 115d and each of the extended output pads 116a, 116b and 116c may be connected to a respective one of the plurality of film conducting wires 133′. In such embodiments, each of the film conducting wires 133′ that is respectively connected to the basic output pads 115a, 115b, 115c and 115d and each of the film conducting wires 133 that is respectively connected to the extended output pads 116a, 116b and 116c may be disposed in turn. That is, one film conducting wire 133′ connected to one extended output pad (e.g., 116a) may be disposed between two film conducting wires 133′ respectively connected to two basic output pads (e.g., 115a and 115b), and one film conducting wire 133′ connected to one basic output pad (e.g., 115b) may be disposed between two film conducting wires 133′ respectively connected to two extended output pads (e.g., 116a and 116b).

According to the embodiments illustrated in FIGS. 8 and 9, the additional output conducting wires connected to the extended output pads 116a, 116b and 116c may not be provided on the available space 137a and 137b. Instead, in the embodiments illustrated in FIG. 9, the extended output pads 116a, 116b and 116c may be electrically connected to respective ones of the plurality of film conducting wires 133′. As described above, according to some embodiments of the inventive concept, more output pads may be disposed per unit area. Further, a display device having a high image quality characteristic may be provided.

FIGS. 1 through 9 conceptually illustrate configurations of the chip on film packages 100 and 100′ to help understanding of the inventive concept. To help understanding of the inventive concept, a form, a configuration and a size of components included in the chip on film packages 100 and 100′ may be exaggerated or reduced. The chip on film package 100 or 100′ may have another physical form or configuration different from those illustrated in FIGS. 1 through 9. FIGS. 1 through 9 do not intend to limit physical forms or configurations of the chip on film packages 100 and 100′.

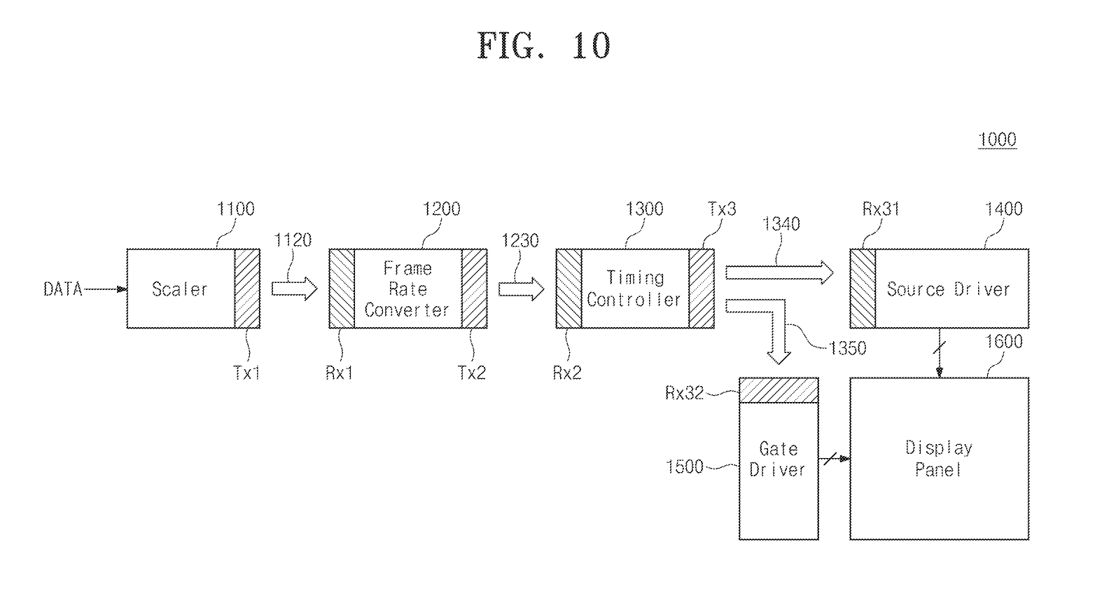

FIG. 10 is a block diagram illustrating a display device including a gate driver and a source driver that are mounted on a chip on film package in accordance with some embodiments of the inventive concept. A display device 1000 may include a scaler 1100, a frame rate converter 1200, a timing controller 1300, a source driver 1400, a gate driver 1500 and a display panel 1600. The display device 1000 may further include differential signal interfaces 1120, 1230, 1340 and 1350 for a signal transmission between components included in the display device 1000.

In some embodiments, each of the differential signal interfaces 1120, 1230, 1340 and 1350 may operate based on at least one of a low voltage differential signaling (LVDS) system, a bus LVDS (B-LVDS) system, a multipoint LVDS (M-LVDS) system and a mini-LVDS system. Alternatively, each of the differential signal interfaces 1120, 1230, 1340 and 1350 may operate based on at least one of not only a low-voltage positive/pseudo emitter-coupled logic (LVPECL) interface, a current-mode logic (CML) interface or a voltage-mode logic (VML) interface but also an advanced intra-panel interface (AIPI) or a high definition multimedia interface (HDMI). However, this is only illustrative and is not to limit a technical spirit of the inventive concept.

Data DATA corresponding to images to be displayed on the display panel 1600 and image information thereof may be provided to the scaler 1100. The scaler 1100 may allow the data DATA to have resolution information corresponding to the images to be displayed on the display panel 1600 by processing the data DATA. The data DATA processed by the scaler 1100 may be provided to the frame rate converter 1200 through the differential signal interface 1120. The differential signal interface 1120 may transmit signals corresponding to the data DATA from a transmit terminal Tx1 to a reception terminal Rx1.

The frame rate converter 1200 may process the data DATA to control a frequency of displaying frames on the display panel 1600, i.e., a “frame rate”. The data DATA processed by the frame rate converter 1200 may be provided to the timing controller 1300 through the differential signal interface 1230. The differential signal interface 1230 may transmit signals corresponding to the data DATA from a transmit terminal Tx2 to a reception terminal Rx2.

The timing controller 1300 may properly distribute the data DATA to the source driver 1400 and the gate driver 1500 in order to control an image displaying of the display panel 1600. In particular, the timing controller 1300 may be implemented to prevent a time difference occurring in an image displaying in a large-sized display device. The timing controller 1300 may distribute the data DATA to the source driver 1400 and the gate driver 1500 through the differential signal interfaces 1340 and 1350, respectively. The differential signal interface 1340 may be implemented to transmit signals between a transmit terminal Tx3 and a reception terminal Rx31, and the differential signal interface 1350 may be implemented to transmit signals between the transmit terminal Tx3 and a reception terminal Rx32.

The source driver 1400 and the gate driver 1500 may provide signals to the display panel 1600 so that intended images are displayed on each pixel of the display panel 1600. The display panel 1600 may display images based on the received signals. In particular, at least one of the source driver 1400 and the gate driver 1500 may be mounted in the form of the chip on film package in accordance with some embodiments of the inventive concept. That is, a plurality of output pads is disposed along two longer sides of an integrated circuit chip facing each other so that a lot of output pads are included in the integrated circuit chip performing a function of the source driver 1400 and the gate driver 1500. Further, to reduce a difference of fan-out between output conducting wires connected to each of the output pads, the output pads may be respectively connected to a plurality of film conducting wires having a form of a straight line. In particular, the plurality of film conducting wires are disposed inside a film as a single layer.

However, a configuration of the display device 1000 illustrated in FIG. 10 is only illustrative. The display device 1000 may further include other components or may not include one or more components shown in FIG. 10. The integrated circuit chip and the chip on film package according to some embodiments of the inventive concept may be utilized to mount other devices or circuits other than the display device 1000.

The configuration illustrated in the block diagram is to help understanding of the inventive concept. Each block may be formed of smaller blocks according to its function. Alternatively, a plurality of blocks may form a larger block according to their function. That is, a technical spirit of the inventive concept is not limited to the configuration illustrated in the block diagram.

According to some embodiments of the inventive concept, a chip on film package including a lot of output pads may be obtained. A size of an integrated circuit chip may be reduced by increasing the number of output pads disposed per unit area. That is, according to some embodiments of the inventive concept, an efficiency of a disposition of output pads may be improved.

According to some embodiments of the inventive concept, a difference of fan-out between output conducting wires respectively connected to output pads disposed along two longer sides of an integrated circuit chip facing each other may be reduced. Thus, when the chip on film package in accordance with the some embodiments of the inventive concept is connected to a display panel, the display device may have a high image quality characteristic.

While the inventive concept has been particularly shown and described with reference to exemplary embodiments thereof, it will be understood by those of ordinary skill in the art that various changes in form and details may be made therein without departing from the spirit and scope of the inventive concept.

What is claimed is:

1. A chip on film package comprising:
an integrated circuit chip comprising:
one or more first output pads along a first edge of a surface of the integrated circuit chip; and
one or more second output pads along a second edge of the surface of the integrated circuit chip, the second edge facing the first edge, a length of the first edge being greater than a length of a third edge of the surface and greater than a length of a fourth edge of the surface, a length of the second edge being greater than the length of the third edge and greater than the length of the fourth edge; and
a film comprising:
a lower film;
a plurality of film conducting wires on a face of the lower film, each of the plurality of film conducting wires spaced apart from any adjacent film conducting wire among the plurality of film conducting wires; and
an upper film on the plurality of film conducting wires,
wherein the one or more first output pads are electrically connected to respective ones of the plurality of film conducting wires,
wherein the one or more second output pads are electrically connected to respective ones of the plurality of film conducting wires,
wherein the plurality of film conducting wires comprises a single layer between the upper film and the lower film, and
wherein each of the plurality of film conducting wires extends under the first edge of the surface of the integrated circuit chip.

2. The chip on film package of claim 1, wherein the one or more first output pads and the one or more second output pads are electrically connected to the respective ones of the plurality of film conducting wires through via-holes, respectively.

3. The chip on film package of claim 2, wherein each of the via-holes penetrates the upper film.

4. The chip on film package of claim 1, wherein the integrated circuit chip further comprises one or more input pads along the second edge of the surface of the integrated circuit chip.

5. The chip on film package of claim 4, wherein the integrated circuit chip comprises more first output pads than second output pads.

6. The chip on film package of claim 1, wherein each of the plurality of film conducting wires has a form of a straight line.

7. The chip on film package of claim 1, wherein the one or more first output pads and the one or more second output pads are alternately disposed in turn when the integrated circuit chip is viewed from the first edge or the second edge.

8. The chip on film package of claim 1, wherein the one or more first output pads and the one or more second output pads are connected to the plurality of film conducting wires in one-to-one correspondence.

9. The chip on film package of claim 8, wherein the respective ones of the film conducting wires connected to the one or more first output pads and the respective ones of the film conducting wires connected to the one or more second output pads are alternately disposed.

10. The chip on film package of claim 1, wherein the integrated circuit chip comprises at least one of a gate driver integrated circuit chip and a source driver integrated circuit chip.

11. A chip on film package comprising:
a film comprising a plurality of film conducting wires inside of the film, each of the plurality of film conducting wires spaced apart from any adjacent film conducting wire among the plurality of film conducting wires; and
an integrated circuit chip on a face of the film, the integrated circuit chip comprising:
one or more first output pads along a first edge of a surface of the integrated circuit chip; and
one or more second output pads along a second edge of the surface of the integrated circuit chip, the second edge facing the first edge, a length of the first edge being greater than a length of a third edge of the surface and greater than a length of a fourth edge of the surface, a length of the second edge being greater than the length of the third edge and greater than the length of the fourth edge,
wherein the one or more first output pads are electrically connected to respective ones of the plurality of film conducting wires,
wherein the one or more second output pads are electrically connected to respective ones of the plurality of film conducting wires,
wherein the plurality of film conducting wires comprises a single layer inside the film, and
wherein each of the plurality of film conducting wires extends under the first edge of the surface of the integrated circuit chip.

12. The chip on film package of claim 11, wherein the one or more first output pads and the one or more second output pads are electrically connected to the respective ones of the plurality of film conducting wires through via-holes, respectively.

13. The chip on film package of claim 12, wherein each of the via-holes penetrates the face of the film.

14. The chip on film package of claim 11, wherein the integrated circuit chip further comprises one or more input pads along the second edge of the surface of the integrated circuit chip, and
wherein the integrated circuit chip comprises more first output pads than second output pads.

15. The chip on film package of claim 11, wherein each of the plurality of film conducting wires has a form of a straight line.

16. The chip on film package of claim 11, wherein the integrated circuit chip comprises at least one of a gate driver integrated circuit chip and a source driver integrated circuit chip.

17. A display system comprising:
a chip on film package comprising:
an integrated circuit chip comprising one or more first output pads along a first edge of a surface of the integrated circuit chip, and one or more second output pads along a second edge of the surface of the integrated circuit chip, the second edge facing the first edge, a length of the first edge being greater than a length of a third edge of the surface and greater than a length of a fourth edge of the surface, a length of the second edge being greater than the length of the third edge and greater than the length of the fourth edge; and
a film comprising a lower film, a plurality of film conducting wires on a face of the lower film, and an upper film on the plurality of film conducting wires, each of the plurality of film conducting wires spaced apart from any adjacent film conducting wire from among the plurality of film conducting wires; and
a display device comprising:
a display panel;
a frame rate converter configured to process data that controls a frequency of frames displayed on the display panel; and
a timing controller configured to control an image displayed on the display panel,
wherein the one or more first output pads and the one or more second output pads are electrically connected to respective ones of the plurality of film conducting wires through via-holes in one-to-one correspondence, and
wherein the plurality of film conducting wires comprises a single layer between the upper film and the lower film.

18. The display system of claim 17, wherein each of the plurality of film conducting wires extends under the first edge of the surface of the integrated circuit chip.

19. The display system of claim 17, wherein the respective ones of the film conducting wires connected to the one or more first output pads and the respective ones of the film conducting wires connected to the one or more second output pads are alternately disposed.

20. The display system of claim 17, wherein the integrated circuit chip comprises at least one of a gate driver integrated circuit chip and a source driver integrated circuit chip.
